(19) United States
(12) Patent Application Publication
(10) Pub. No.: US 2026/0353546 A1
(43) Pub. Date: Nov. 5, 2026

(54) DUAL-SIDED HEAT-DISSIPATING CIRCUIT BOARD

(71) Applicant: ZF Friedrichshafen AG, Friedrichshafen (DE)

(72) Inventors: Shaozhi Yuan, Shanghai (CN); Qing Xu, Shanghai (CN)

(73) Assignee: ZF Friedrichshafen AG, Friedrichshafen (DE)

(21) Appl. No.: 19/664,008

(22) Filed: Apr. 30, 2026

(30) Foreign Application Priority Data
Apr. 30, 2025 (CN) 202510569929.4

(51) Int. Cl. H05K 1/02; H05K 1/185

(52) U.S. Cl. CPC H05K 1/0204; H05K 1/185; H05K 2201/10545

(57) ABSTRACT

A double-sided heat-dissipating circuit board including: a chip-embedded circuit board including a circuit board and a chip module embedded in the circuit board, the chip module being led out from a front side of the circuit board; a first heat-dissipating assembly disposed on a front side of the chip-embedded circuit board, the first heat-dissipating assembly including a first thermally conductive insulating layer attached to the front side of the circuit board and a first heat-dissipating member assembled with the first thermally conductive insulating layer; and a second heat-dissipating assembly disposed on a back side of the chip-embedded circuit board, the second heat-dissipating assembly including a second thermally conductive insulating layer laminated to a back side of the circuit board and a second heat-dissipating member assembled with the second thermally conductive insulating layer. The chip module is embedded in the circuit board, such that surfaces of the circuit board are planar.

### CROSS-REFERENCE TO RELATED APPLICATION

This application claims priority to Chinese Patent Application No. 202510569929.4, filed on Apr. 30, 2025, the entirety of which is hereby fully incorporated by reference herein.

### Technical Field

The present disclosure relates to the technical field of circuit boards, and specifically relates to a double-sided heat-dissipating circuit board.

### BACKGROUND

A circuit board generates a lot of heat during operation and requires heat dissipation. A conventional circuit board has electronic components attached to a front side, and thus a heat sink can only be disposed on a back side, making it impossible to directly and efficiently achieve heat dissipation of the electronic components.

It should be noted that information disclosed in the above background art section is only used to enhance the understanding of the background of the present disclosure, and therefore may include information that does not constitute the prior art known to those of ordinary skill in the art.

### SUMMARY

In view of this, the present disclosure provides a double-sided heat-dissipating circuit board, where a chip module is embedded in a circuit board, such that surfaces of the circuit board are planar, and heat-dissipating assemblies are disposed on both a front side and a back side of the circuit board, thereby directly and efficiently achieving heat dissipation of electronic components such as the chip module.

According to an aspect of the present disclosure, a double-sided heat-dissipating circuit board is provided. The double-sided heat-dissipating circuit board includes: a chip-embedded circuit board including a circuit board and a chip module embedded in the circuit board, the chip module being led out from a front side of the circuit board; a first heat-dissipating assembly disposed on a front side of the chip-embedded circuit board, the first heat-dissipating assembly including a first thermally conductive insulating layer attached to the front side of the circuit board and a first heat-dissipating member assembled with the first thermally conductive insulating layer; and a second heat-dissipating assembly disposed on a back side of the chip-embedded circuit board, the second heat-dissipating assembly including a second thermally conductive insulating layer laminated to a back side of the circuit board and a second heat-dissipating member assembled with the second thermally conductive insulating layer.

In some embodiments, the first thermally conductive insulating layer is a thermally conductive adhesive or a thermally conductive pad.

In some embodiments, the first heat-dissipating member is a convective heat-dissipating member including: a first heat-dissipating element attached to the first thermally conductive insulating layer; and a first cooling housing assembled with the first heat-dissipating element, where a first cooling space for the circulation of a cooling medium is formed between the first cooling housing and the first heat-dissipating element.

In some embodiments, heat-dissipating pin fins are distributed on a surface of the first heat-dissipating element facing the first cooling housing.

In some embodiments, the first heat-dissipating member is a conductive heat-dissipating member including: a first heat-absorbing module attached to the first thermally conductive insulating layer; and a first heat-dissipating module in contact with the first heat-absorbing module, where the first heat-absorbing module at least partially covers a lead region of the chip module.

In some embodiments, the first heat-absorbing module is a copper block, the first heat-dissipating module is a plastic plate, and the first heat-absorbing module is connected to the first heat-dissipating module by injection molding.

In some embodiments, a lead region of the chip module is partially exposed by the first heat-dissipating member.

In some embodiments, the second thermally conductive insulating layer is a resin layer.

In some embodiments, the second heat-dissipating member is a convective heat-dissipating member including: a second heat-dissipating element laminated to the second thermally conductive insulating layer; and a second cooling housing assembled with the second heat-dissipating element, where a second cooling space for the circulation of a cooling medium is formed between the second cooling housing and the second heat-dissipating element.

In some embodiments, heat-dissipating pin fins are distributed on a surface of the second heat-dissipating element facing the second cooling housing.

Compared with the prior art, the present disclosure has at least the following beneficial effects.

In the double-sided heat-dissipating circuit board of the present disclosure, the chip module is embedded in the circuit board, such that surfaces of the circuit board are planar, allowing the heat-dissipating assemblies to be disposed on both the front side and the back side of the circuit board, thereby directly and efficiently achieving heat dissipation of electronic components such as the chip module.

The heat-dissipating assemblies disposed on the front side and the back side of the chip-embedded circuit board achieve insulation protection and heat conduction through their respective thermally conductive insulating layers, and achieve efficient heat dissipation through their respective heat-dissipating members. Moreover, the first thermally conductive insulating layer is attached to the front side of the circuit board, thereby avoiding damage to the chip module by process operations such as hot pressing; and the second thermally conductive insulating layer is laminated to the back side of the circuit board, allowing a thermally conductive material having higher thermal conductivity to be selected, thereby improving the overall heat dissipation effect.

It should be understood that the above general description and the following detailed description are only exemplary and explanatory, and cannot limit the present disclosure.

### BRIEF DESCRIPTION OF THE DRAWINGS

The accompanying drawings herein, which are incorporated into and form a part of the description, illustrate embodiments consistent with the present disclosure and, together with the description, are used to explain principles of the present disclosure. Obviously, the accompanying drawings described below show merely some of the embodiments of the present disclosure, and those of ordinary skill in the art would also have obtained other accompanying drawings according to these accompanying drawings without any creative effort.

FIG. 1 is a schematic structural diagram of a double-sided heat-dissipating circuit board according to an embodiment of the present disclosure; and

FIG. 2 is a schematic structural diagram of a further double-sided heat-dissipating circuit board according to an embodiment of the present disclosure.

### DETAILED DESCRIPTION

Now exemplary implementations will be described more fully with reference to the accompanying drawings. However, the exemplary implementations can be implemented in many forms and should not be construed as being limited to the implementations described herein. On the contrary, these implementations are provided to make the present disclosure more thorough and complete, and to fully convey the concept of the exemplary implementations to those skilled in the art.

The accompanying drawings are only schematic illustrations of the present disclosure and are not necessarily drawn to scale. In the accompanying drawings, the same reference numerals denote the same or similar parts, and thus the repeated description thereof will be omitted.

The terms "first," "second," and similar terms used in the specific description do not denote any order, quantity, or importance, but are merely used to distinguish between different components. In the description of the present disclosure, it should be noted that orientations or positional relationships indicated by the terms such as "front side" and "back side" are based on orientations or positional relationships shown in the drawings, which is only for convenience of describing the present disclosure and simplifying the description, rather than indicating or implying that an apparatus or an element referred to must have a specific orientation or be constructed and operated in a specific orientation, and therefore cannot be construed as limiting the present disclosure. Moreover, in the description of the present disclosure, when it is said that a device is “in contact with” or “connected to” another device, this includes not only the case of direct contact or direct connection but also the case of indirect contact or indirect connection through other elements.

It should be noted that the embodiments in the present disclosure and features of the various embodiments can be combined with each other without conflict.

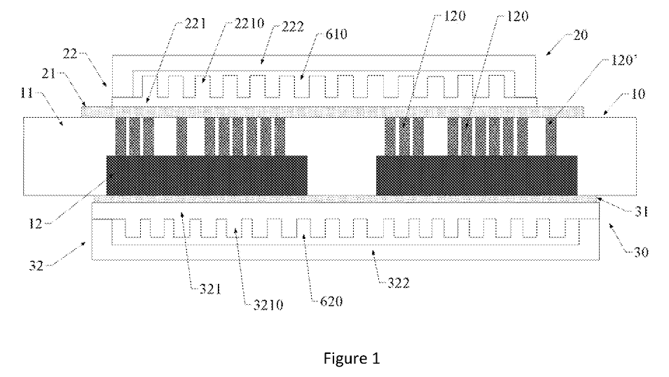

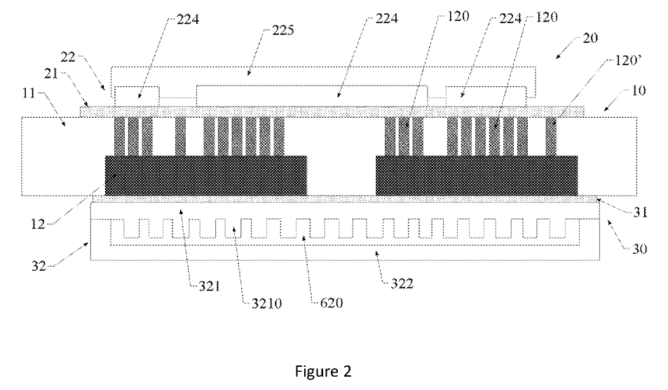

FIGS. 1 and 2 illustrate the structures of two types of double-sided heat-dissipating circuit boards according to embodiments of the present disclosure. As shown with reference to FIGS. 1 and 2, a double-sided heat-dissipating circuit board according to an embodiment of the present disclosure includes:
a chip-embedded circuit board 10 including a circuit board 11 and a chip module 12 embedded in the circuit board 11, the chip module 12 being led out from a front side of the circuit board 11;
a first heat-dissipating assembly 20 disposed on a front side of the chip-embedded circuit board 10, the first heat-dissipating assembly 20 including a first thermally conductive insulating layer 21 attached to the front side of the circuit board 11 and a first heat-dissipating member 22 assembled with the first thermally conductive insulating layer 21; and
a second heat-dissipating assembly 30 disposed on a back side of the chip-embedded circuit board 10, the second heat-dissipating assembly 30 including a second thermally conductive insulating layer 31 laminated to a back side of the circuit board 11 and a second heat-dissipating member 32 assembled with the second thermally conductive insulating layer 31.

In the double-sided heat-dissipating circuit board of the present disclosure, the chip module 12 is embedded in the circuit board 11, such that surfaces of the circuit board 11 are planar, allowing the heat-dissipating assemblies to be disposed on both the front side and the back side of the circuit board 11, thereby directly and efficiently achieving heat dissipation of electronic components such as the chip module 12.

The heat-dissipating assemblies disposed on the front side and the back side of the chip-embedded circuit board 10 achieve insulation protection and heat conduction through their respective thermally conductive insulating layers and achieve efficient heat dissipation through their respective heat-dissipating members. Moreover, the first thermally conductive insulating layer 21 is attached to the front side of the circuit board 11, thereby avoiding damage to the chip module 12 by process operations such as hot pressing; and the second thermally conductive insulating layer 31 is laminated to the back side of the circuit board 11, allowing a thermally conductive material having higher thermal conductivity to be selected, thereby improving the overall heat dissipation effect.

In some embodiments, the first thermally conductive insulating layer 21 is a thermally conductive adhesive or a thermally conductive pad. A thermally conductive material such as the thermally conductive adhesive or the thermally conductive pad is attached to the front side of the circuit board 11 to complete assembly, without the need for process operations such as hot pressing and curing, thereby effectively protecting the chip module 12 and avoiding damage to the chip module 12.

In some embodiments, as shown with reference to FIG. 1, the first heat-dissipating member 22 is a convective heat-dissipating member including: a first heat-dissipating element 221 attached to the first thermally conductive insulating layer 21; and a first cooling housing 222 assembled with the first heat-dissipating element 221, where a first cooling space 610 for the circulation of a cooling medium is formed between the first cooling housing 222 and the first heat-dissipating element 221.

The convective heat-dissipating member achieves cooling mainly by means of the cooling medium such as a cooling liquid or a cooling gas. The first cooling housing 222 and the first heat-dissipating element 221 may be pre-assembled with each other by means of fasteners and then integrally attached to the first thermally conductive insulating layer 21, such that the first heat-dissipating element 221 is slightly embedded in the first thermally conductive insulating layer 21 and fixed thereto by surface bonding. The first cooling space 610 may be connected to a cooling medium supply line and a cooling medium discharge line via cooling ports (not specifically shown in the figure).

The first heat-dissipating element 221 may be an aluminum component having a good heat conduction and heat dissipation effect. The first cooling housing 222 may be a plastic component, which is not limited thereto.

Further, in some embodiments, heat-dissipating pin fins 2210 are distributed on a surface of the first heat-dissipating element 221 facing the first cooling housing 222. By means of the heat-dissipating pin fins 2210, a heat dissipation area and a contact area with the cooling medium are increased, thereby improving the heat dissipation effect.

In some embodiments, as shown with reference to FIG. 2, the first heat-dissipating member 22 is a conductive heat-dissipating member including: a first heat-absorbing module 224 attached to the first thermally conductive insulating layer 21; and a first heat-dissipating module 225 in contact with the first heat-absorbing module 224, where the first heat-absorbing module 224 at least partially covers a lead region 120 of the chip module 12.

The conductive heat-dissipating member achieves heat dissipation mainly through heat conduction. The first heat-absorbing module 224 is in contact with a heat source to absorb heat generated by the chip module 12, in particular to achieve rapid heat absorption under a transient high-power operating condition of the chip module 12, and temporarily store the heat inside the first heat-absorbing module 224. Subsequently, the first heat-absorbing module 224 performs natural heat dissipation, and the heat is further dissipated by means of the first heat-dissipating module 225.

The first heat-absorbing module 224 may be a copper block. Copper has excellent thermal conductivity and can rapidly absorb and dissipate heat. The first heat-dissipating module 225 may be a plastic plate, which is not limited thereto. The first heat-absorbing module 224 may be connected to the first heat-dissipating module 225 by injection molding to form the first heat-dissipating member 22 of an integral structure, which is then attached to the first thermally conductive insulating layer 21, such that the first heat-absorbing module 224 is slightly embedded in the first thermally conductive insulating layer 21 and fixed thereto by surface bonding.

As shown with continued reference to FIGS. 1 and 2, in some embodiments, the lead region 120 of the chip module 12 is partially exposed by the first heat-dissipating member 22. For example, a gate lead region 120' may be exposed. In this way, wiring of the chip module 12 may be facilitated.

In some embodiments, the second thermally conductive insulating layer 31 is a resin layer. Resin has good thermal conductivity and may improve the heat dissipation effect. Moreover, the resin layer may be fixed by hot pressing using a press, without damaging the chip module 12.

In some embodiments, the second heat-dissipating member 32 is a convective heat-dissipating member including: a second heat-dissipating element 321 laminated to the second thermally conductive insulating layer 31; and a second cooling housing 322 assembled with the second heat-dissipating element 321, where a second cooling space 620 for the circulation of a cooling medium is formed between the second cooling housing 322 and the second heat-dissipating element 321.

When the second heat-dissipating member 32 is assembled, the second heat-dissipating element 321 may be first attached to the second thermally conductive insulating layer 31, and the second thermally conductive insulating layer 31 may then be laminated between the second heat-dissipating element 321 and the back side of the circuit board 11 by hot pressing using a press; next, the second cooling housing 322 may be assembled to the second heat-dissipating element 321 by means of assembly parts such as fasteners. The second cooling space 620 may be connected to a cooling medium supply line and a cooling medium discharge line via cooling ports (not specifically shown in the figures).

The second heat-dissipating element 321 may be an aluminum component having a good heat conduction and heat dissipation effect. The second cooling housing 322 may be a plastic component, which is not limited thereto.

Further, in some embodiments, heat-dissipating pin fins 3210 are distributed on a surface of the second heat-dissipating element 321 facing the second cooling housing 322. By means of the heat-dissipating pin fins 3210, the heat dissipation area and the contact area with the cooling medium are increased, thereby improving the heat dissipation effect.

In summary, in the double-sided heat-dissipating circuit board of the present disclosure, the chip module 12 is embedded in the circuit board 11, such that surfaces of the circuit board 11 are planar, allowing the heat-dissipating assemblies to be disposed on both the front side and the back side of the circuit board 11, thereby directly and efficiently achieving heat dissipation of electronic components such as the chip module 12. The heat-dissipating assemblies disposed on the front side and the back side of the chip-embedded circuit board 10 achieve insulation protection and heat conduction through their respective thermally conductive insulating layers, and achieve efficient heat dissipation through their respective heat-dissipating members. The first thermally conductive insulating layer 21 is attached to the front side of the circuit board 11, thereby avoiding damage to the chip module 12 by process operations such as hot pressing. The first heat-dissipating member 22 may be a convective heat-dissipating member or a conductive heat-dissipating member as required. The second thermally conductive insulating layer 31 is laminated to the back side of the circuit board 11, allowing a thermally conductive material having higher thermal conductivity to be selected, and the second heat-dissipating member 32 may be a convective heat-dissipating member, thereby improving the overall heat dissipation effect.

The above is a further detailed description of the present disclosure with reference to the specific preferred implementations, and it cannot be considered that the specific implementation of the present disclosure is limited to these descriptions. For those of ordinary skill in the art of the present disclosure, several simple deductions or substitutions can be further made without departing from the concept of the present disclosure, and should be regarded as falling within the scope of protection of the present disclosure.

1. A double-sided heat-dissipating circuit board, comprising:
a chip-embedded circuit board comprising a circuit board and a chip module embedded in the circuit board, the chip module being led out from a front side of the circuit board;
a first heat-dissipating assembly disposed on a front side of the chip-embedded circuit board, the first heat-dissipating assembly comprising a first thermally conductive insulating layer attached to the front side of the circuit board and a first heat-dissipating member assembled with the first thermally conductive insulating layer; and
a second heat-dissipating assembly disposed on a back side of the chip-embedded circuit board, the second heat-dissipating assembly comprising a second thermally conductive insulating layer laminated to a back side of the circuit board and a second heat-dissipating member assembled with the second thermally conductive insulating layer.

2. The double-sided heat-dissipating circuit board according to claim 1, wherein the first thermally conductive insulating layer is a thermally conductive adhesive or a thermally conductive pad.

3. The double-sided heat-dissipating circuit board according to claim 1, wherein the first heat-dissipating member is a convective heat-dissipating member comprising:
a first heat-dissipating element attached to the first thermally conductive insulating layer; and
a first cooling housing assembled with the first heat-dissipating element,
wherein a first cooling space for circulation of a cooling medium is formed between the first cooling housing and the first heat-dissipating element.

4. The double-sided heat-dissipating circuit board according to claim 3, wherein heat-dissipating pin fins are distributed on a surface of the first heat-dissipating element facing the first cooling housing.

5. The double-sided heat-dissipating circuit board according to claim 1, wherein the first heat-dissipating member is a conductive heat-dissipating member comprising:
a first heat-absorbing module attached to the first thermally conductive insulating layer; and
a first heat-dissipating module in contact with the first heat-absorbing module,
wherein the first heat-absorbing module at least partially covers a lead region of the chip module.

6. The double-sided heat-dissipating circuit board according to claim 5, wherein the first heat-absorbing module is a copper block, the first heat-dissipating module is a plastic plate, and the first heat-absorbing module is connected to the first heat-dissipating module by injection molding.

7. The double-sided heat-dissipating circuit board according to claim 1, wherein a lead region of the chip module is partially exposed by the first heat-dissipating member.

8. The double-sided heat-dissipating circuit board according to claim 1, wherein the second thermally conductive insulating layer is a resin layer.

9. The double-sided heat-dissipating circuit board according to claim 1, wherein the second heat-dissipating member is a convective heat-dissipating member comprising:
a second heat-dissipating element laminated to the second thermally conductive insulating layer; and
a second cooling housing assembled with the second heat-dissipating element,
wherein a second cooling space for circulation of a cooling medium is formed between the second cooling housing and the second heat-dissipating element.

10. The double-sided heat-dissipating circuit board according to claim 9, wherein heat-dissipating pin fins are distributed on a surface of the second heat-dissipating element facing the second cooling housing.
